(19) United States
(12) Patent Application Publication
(10) Pub. No.: US 2009/0085192 A1
(43) Pub. Date: Apr. 2, 2009

(54) Packaging substrate structure having semiconductor chip embedded therein and fabricating method thereof

(75) Inventors: Shih-Ping Hsu, Sinfong Township (TW); Shang-Wei Chen, Sinfong Township (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/285,259

(22) Filed: Oct. 1, 2008

(30) Foreign Application Priority Data
Oct. 1, 2007 (TW) 096136723

(51) Int. Cl. H01L 23/485; H01L 21/58

(52) U.S. Cl. 257/700; 438/118; 257/E21.505; 257/E23.02

(57) ABSTRACT

The present invention relates to a packaging substrate structure having an semiconductor chip embedded therein and a method for manufacturing the same. The structure comprises: a substrate body having a through cavity, wherein the substrate body is a multilayer board which comprises a core board and a first built-up structure disposed on each of the opposite surfaces of the core board; an semiconductor chip disposed and fixed in the cavity, wherein the active surface of the semiconductor chip has a plurality of electrode pads thereon; and a second built-up structure disposed on at least one surface of the substrate body as well as the surface of the semiconductor chip, wherein the second built-up structure has a plurality of conductive vias conducting to the first built-up structure. The present invention can reduce the stress imposed on the surface of the semiconductor chip and increase the reliability of the whole package structure.

### BACKGROUND OF THE INVENTION

1. Field of the Invention

The present invention relates to a packaging substrate structure having an semiconductor chip embedded therein and a method for manufacturing the same and, particularly relates to a packaging substrate structure with an semiconductor chip embedded therein having improved yield and a method for manufacturing the same.

2. Description of Related Art

Customer demands of the electronics industry continue to evolve rapidly and the main trends are high integration and miniaturization. In order to satisfy those requirements, especially in the packaging of semiconductor devices, development of circuit boards with the maximum of active and passive components and conductive wires has progressed from single to multiple layer types. This means that a greater circuit layout area is available due to interlayer connection technology. Accordingly, more circuits and electronic components per unit volume of the packaging substrate can be arranged therein.

In conventional methods, many studies relative to methods of embedding semiconductor chip within a substrate have appeared in recent years. According to the method used in the present industrial manufacture, built-up structures are often formed on the chips and on the substrate at the same time after the embedding process of the chips. As a perspective view of a packaging substrate structure 10 shown in FIG. 1, for example, the process of providing the packaging substrate structure 10 comprises: forming a cavity 115 in the core board 11 having wiring layers 111 thereon, embedding a chip 15 in the cavity 115, filling the gap between the chip 15 and the cavity 115 with an adhesive material 16 to fix the chip 15 in the cavity 115 of the core board 11. Then, forming a built-up structure 13 on the surfaces of the chip 15 and the core board 11 by build-up methods, in which the built-up structure 13 has a dielectric layer 130, a wiring layer 131 disposed on the surface of the dielectric layer 130, and conductive vias 134 disposed in the dielectric layer 130. The conductive vias 134 are used for electrical connections of the wiring layer 111 of the substrate 11 and the wiring layer 131 of the substrate 13.

The built-up structure is formed not only on the surface of the core board, but also on the chip. The more the layers of the built-up structure, the larger the stress imposed on the chip, thereby the reliability of the whole package structure is weakened. Besides, if the yield of the packaging substrate decreases caused by the increasing number of layers, more good chips embedded in the substrate will be compromised, which means a higher manufacturing cost will be incurred. Also, the transmiting efficiency is reduced because of the long transmiting path owing to the numerous built-up substrates disposed on the chip, and noise interference is increased leading to a drop in the electrical quality. Accordingly, in order to provide a package structure with reduced thickness, high performance, and high flexibility, it is necessary to obviate the aforementioned problems.

### SUMMARY OF THE INVENTION

In view of the above conventional shortcomings, one object of the present invention is to provide a packaging substrate having an semiconductor chip embedded therein and the method for fabricating the same, so as to enhance electrical quality of the semiconductor chip embedded therein, reduce stress imposed on the surface of the chips, and improve the yield of the package structure.

To achieve the foregoing object, the present invention provides a packaging substrate structure having an semiconductor chip embedded therein, which comprises: a substrate body having a through cavity, wherein the substrate body is a multi-layer board comprising a core board and a first built-up structure disposed on each of the opposite surfaces of the core board, and the first built-up structure has at least one first dielectric layer, at least one first wiring layer disposed on the first dielectric layer, and a plurality of first conductive vias electrically connecting to the first wiring layer; an semiconductor chip disposed and fixed in the cavity, wherein the semiconductor chip has an active surface and an opposite inactive surface, the active surface of the semiconductor chip has a plurality of electrode pads thereon; and a second built-up structure disposed on at least one surface of the substrate body as well as one surface of the semiconductor chip, wherein the second built-up structure has at least one second dielectric layer, at least one second wiring layer disposed on the second dielectric layer, and a plurality of second conductive vias, in which parts of the second conductive vias electrically connect to the first built-up structure, and the outermost second wiring layer has a plurality of conductive pads.

In the aforementioned structure, another parts of the second conductive vias of the second built-up structure, disposed on the active surface of the semiconductor chip as well as the surface of the substrate body, electrically connect to the electrode pads of the semiconductor chip. Further, the gap between the semiconductor chip and the cavity is filled with an adhesive material or part of the material of the second dielectric layer to thereby fix the semiconductor chip in the cavity.

Besides, the aforementioned structure may further comprise a solder mask covering one surface of the second built-up structure, wherein the solder mask has a plurality of openings to expose the conductive pads; or the aforementioned structure may further comprise a solder mask covering one surface having no second built-up structure thereon of the substrate body and covering one surface of the semiconductor chip. When the surface of the semiconductor chip is an active surface, a plurality of openings will be formed in the solder mask to expose the electrode pads disposed on the active surface of the semiconductor chip.

The present invention further provides a method of fabricating the packaging substrate structure having an semiconductor chip embedded therein, which comprises: providing a substrate body having a through cavity, wherein the substrate body is a multilayer board which comprises a core board and a first built-up structure disposed on each of the opposite surfaces of the core board, the first built-up structure having at least one first dielectric layer, at least one first wiring layer disposed on the first dielectric layer, and a plurality of first conductive vias electrically connecting to the first wiring layer; placing and fixing an semiconductor chip in the cavity, wherein the semiconductor chip has an active surface and an opposite inactive surface, the active surface has a plurality of electrode pads thereon; and forming a second built-up structure on at least one surface of the substrate body as well as one surface of the semiconductor chip, wherein the second built-up structure has at least one second dielectric layer, at least one second wiring layer disposed on the second dielectric layer, and a plurality of second conductive vias, in which parts of the second conductive vias electrically connect to the first built-up structure, and the outermost second wiring layer has a plurality of conductive pads.

In the aforementioned method, another parts of the second conductive vias of the second built-up structure formed on the active surface of the semiconductor chip as well as the surface of the substrate body electrically connect to the electrode pads of the semiconductor chip. Besides, the fixing of the semiconductor chip in the cavity is performed by filling the gap between the semiconductor chip and the cavity with an adhesive material, or with part of the material of the second dielectric layer.

The aforementioned method further comprises: forming a solder mask covering one surface of the second built-up structure, and forming a plurality of openings in the solder mask to expose the conductive pads. Also, the aforementioned method may further comprise: forming a solder mask covering one surface having no second built-up structure thereon of the substrate body and covering the surface of the semiconductor chip. When the surface of the semiconductor chip is an active surface, a plurality of openings will be formed in the solder mask to expose the electrode pads on the active surface of the semiconductor chip.

Namely, according to the packaging substrate structure having an semiconductor chip embedded therein and the method for manufacturing the same of the present invention, the number of layers of the built-up structure disposed in the upper position of the semiconductor chip of the packaging substrate structure is less than that of the conventional packaging substrate structure. As a result, the stress imposed on the surface of the semiconductor chip can be reduced and the reliability of the whole package structure can be increased. Besides, the problem of the low yield of the packaging substrate due to the increasing number of layers, that further causes scrapping of the good chips embedded in the substrate, can be avoided. Also, the transmiting efficiency is enhanced because of the shortening of the transmiting path, and noise interference is diminished so as to enhance electrical quality.

### BRIEF DESCRIPTION OF THE DRAWINGS

FIG. 1 is a perspective view of a packaging substrate structure known in the art;

FIGS. 2A to 2E′ show a flow chart for manufacturing a packaging substrate structure having an semiconductor chip embedded therein of the Example 1;

FIGS. 3A to 3E′ show a flow chart for manufacturing a packaging substrate structure having an semiconductor chip embedded therein of the Example 2; and

FIGS. 4A to 4E′ show a flow chart for manufacturing a packaging substrate structure having an semiconductor chip embedded therein of the Example 3.

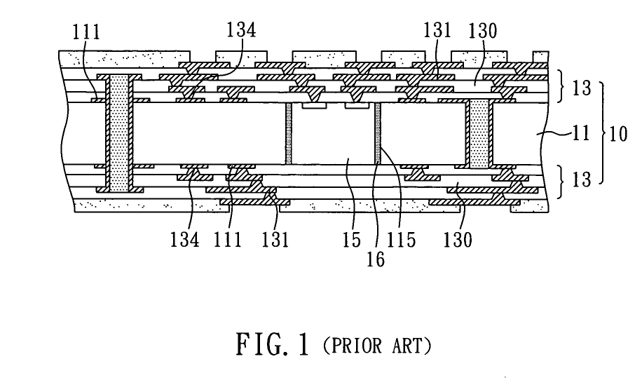

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

### EXAMPLE 1

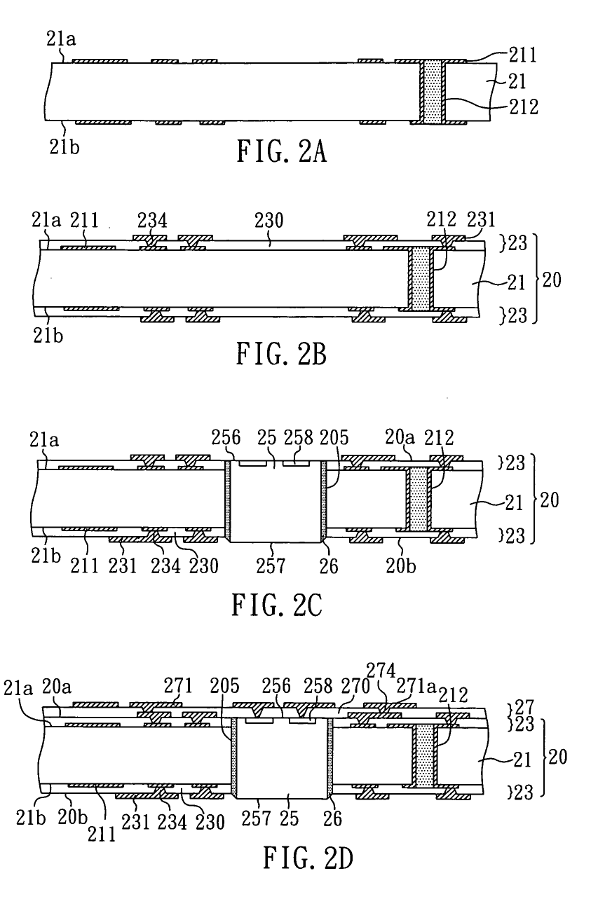

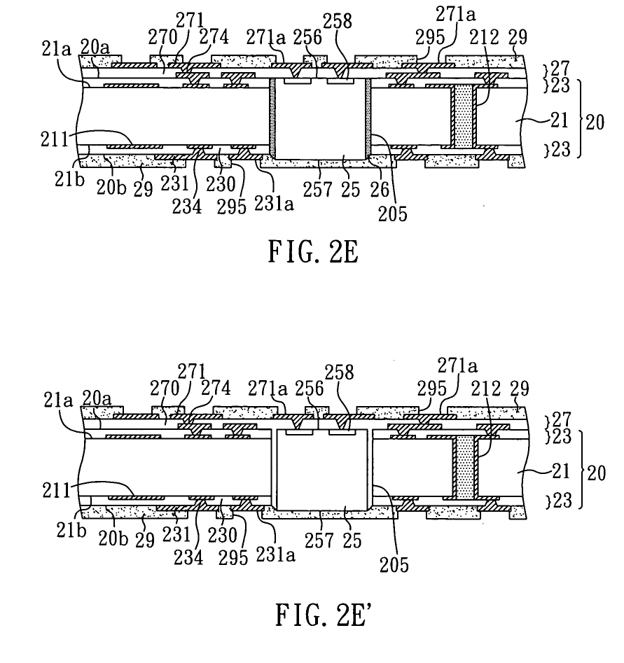

With reference to FIGS. 2A to 2E′, there is shown a flow chart for manufacturing a packaging substrate structure having an semiconductor chip embedded therein in the present example.

As shown in FIG. 2A, a core board 21 is provided first. This core board 21 has wiring layers 211 disposed on the surface of the core board 21 and a conductive through hole 212 extending through the core board 21. The two wiring layers 211 disposed respectively on the two surfaces 21a, 21b of the core board 21 are electrically connected to each other by the conductive through hole 212.

Then as shown in FIG. 2B, a first built-up structure 23 is formed on each surface of the core board 21 together with the wiring layer 211. The first built-up structure 23 has at least one first dielectric layer 230, at least one first wiring layer 231 disposed on the first dielectric layer 230, and a plurality of first conductive vias 234 electrically connecting to the first wiring layer 231.

The method of providing the first built-up structure 23 is well known to one skilled in this art and is not detailed introduced here.

Thus, a substrate body 20 with multi-layered structure is provided after the first built-up structure 23 has been formed on each surface of the core board 21 together with the wiring layer 211.

Referring to FIG. 2C, a through cavity 205 is formed in the substrate body 20, then an semiconductor chip 25 is placed and fixed in the cavity 205. Wherein, the semiconductor chip 25 has an active surface 256 and an opposite inactive surface 257, and the active surface 256 has a plurality of electrode pads 258 thereon. Herein, the fixing of the semiconductor chip 25 in the cavity 205 is performed by filling the gap between the semiconductor chip 25 and the cavity 26 with an adhesive material 25.

Afterwards, with reference to FIG. 2D, a second built-up structure 27 is formed on one surface 20a of the substrate body 20 as well as the active surface 256 of the semiconductor chip 25. The second built-up structure 27 has at least one second dielectric layer 270, at least one second wiring layer 271 disposed on the second dielectric layer 270, and a plurality of second conductive vias 274, in which parts of the second conductive vias 274 electrically connect to the first built-up structure 23. The second wiring layer 271 has a plurality of conductive pads 271a. Another parts of the second conductive vias 274 electrically connect to the electrode pads 258 of the semiconductor chip 25, thus a packaging substrate structure having an semiconductor chip embedded therein is completed.

Then, in reference to FIG. 2E, a solder mask 29 is formed on the second built-up structure 27, and a plurality of openings 295 are formed in the solder mask 29 to expose the conductive pads 271a. Simultaneously, a solder mask 29 is formed on another surface 20b of the substrate body 20 as well as the inactive surface 257 of the semiconductor chip 25, in which a plurality of openings 295 are formed in the solder mask 29 to expose the first wiring layer 231 as conductive pads 271a.

In the above method, the fixing of the semiconductor chip 25 in the cavity 205 is performed by filling the gap between the semiconductor chip 25 and the cavity 205 with part of the material of the second dielectric layer 270, as shown in FIG. 2E′.

The present invention also provides a packaging substrate structure having an semiconductor chip embedded therein, referring to FIG. 2E and 2E′, comprising: a substrate body 20 having a through cavity 205, wherein the substrate body 20 is a multilayer board which comprises a core board 21, and first built-up structures 23 disposed respectively on the opposite surfaces of the core board 21. The first built-up structure 23 has at least one first dielectric layer 230, at least one first wiring layer 231 disposed on the first dielectric layer 230, and a plurality of first conductive vias 234 electrically connecting to the first wiring layer 231; an semiconductor chip 25 disposed and fixed in the cavity 205, wherein the semiconductor chip 25 has an active surface 256 and an opposite inactive surface 257, the active surface 256 of the semiconductor chip 25 has a plurality of electrode pads 258 thereon; and a second built-up structure 27 disposed on one surface 20a of the substrate body 20 as well as the active surface 256 of the semiconductor chip 25, wherein the second built-up structure 27 has at least one second dielectric layer 270, at least one second wiring layer 271 disposed on the second dielectric layer 270, and a plurality of second conductive vias 274, in which parts of the second conductive vias 274 electrically connect to the first built-up structure 23, another parts of the second conductive vias 274 electrically connect to the electrode pads 258 of the semiconductor chip 25, and the outermost second wiring layer 271 has a plurality of conductive pads 271a. A solder mask 29 disposed in the surface of the second built-up structure 27 has a plurality of openings 295 to expose the conductive pads 271a. Also a solder mask 29 is formed on another surface 20b of the substrate body 20 as well as the inactive surface 257 of the semiconductor chip 25, in which a plurality of openings 295 are formed in the solder mask 29 to expose the first wiring layer 231 as conductive pads 271a.

### EXAMPLE 2

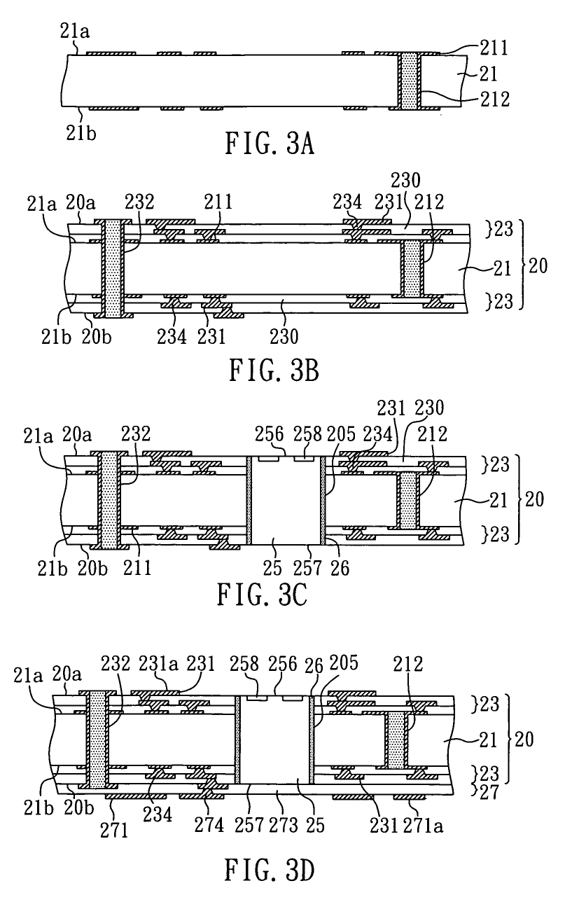

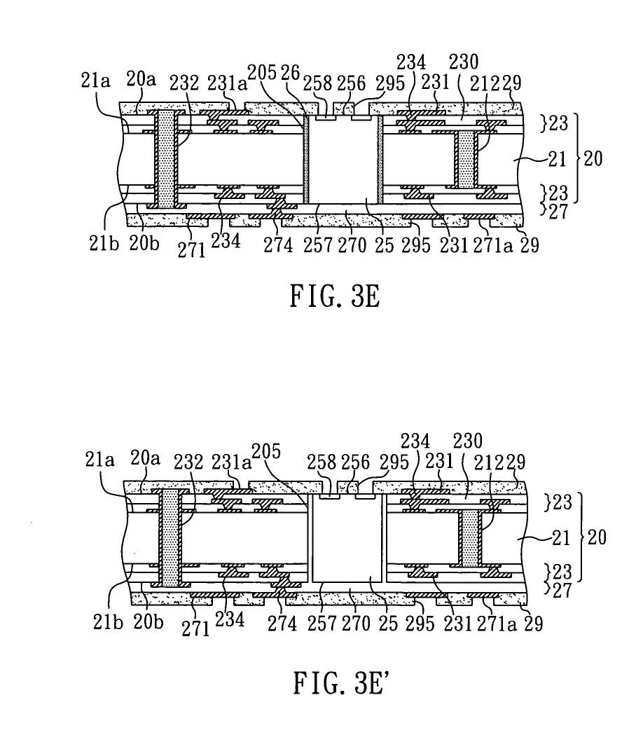

In reference with FIGS. 3A to 3E′, the flow chart for manufacturing a packaging substrate structure having an semiconductor chip embedded therein in the present example is shown. The method of the present example is the same as that of Example 1, except that, after the formation of the first built-up structure 23 and embedding of the semiconductor chip 25, a second built-up structure 27 is additionally formed on the inactive surface 257 of the semiconductor chip 25 as well as the surface 20b of the substrate body 20, as represented in FIG. 3D. Further, a conductive through hole 232 is formed through the substrate body 20 except the conductive through hole 212. With reference to FIG. 3E and 3E′, a solder mask 29 is formed covering one surface 20a (having no second built-up structure 27 thereon) of the substrate body 20 and covering the active surface 256 of the semiconductor chip 25, in which a plurality of openings 295 are formed in the solder mask 29 to expose the electrode pads 258 of the active surface 256 of the semiconductor chip 25. The process steps of providing the packaging substrate structure of the present example are reference to those of Example 1, which are not further discussed here.

### EXAMPLE 3

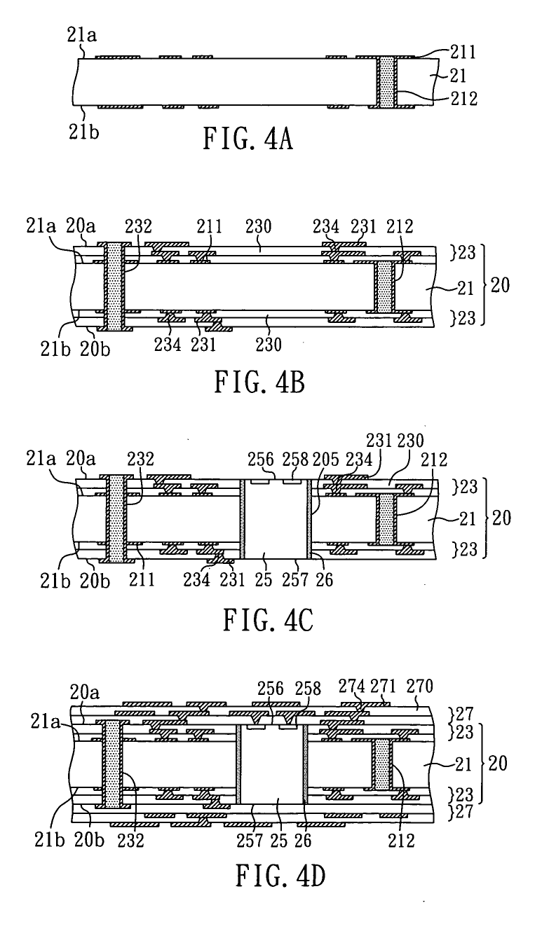

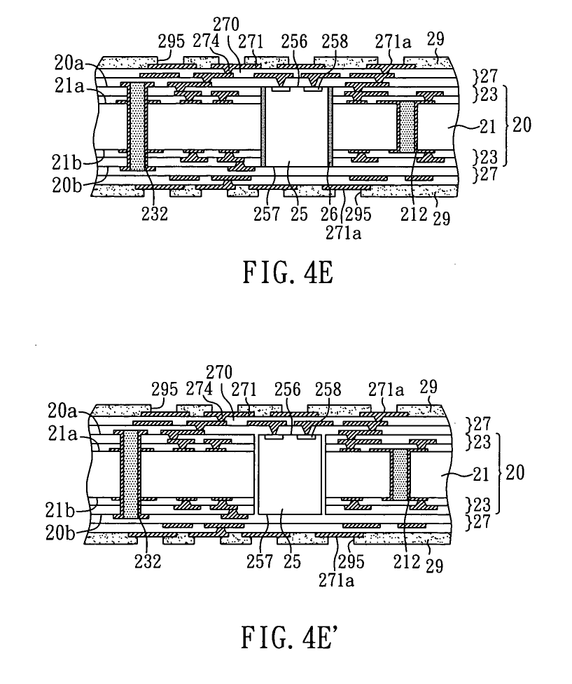

In reference with FIGS. 4A to 4E′, the flow chart for manufacturing a packaging substrate structure having an semiconductor chip embedded therein in the present example is shown. The difference between the present example and the previous two examples is that the second built-up structure 27 is formed on each of the opposite surfaces 20a and 20b of the substrate body 20 as shown in FIG. 4D. The process steps of providing the packaging substrate structure of the present example are reference to those of Example 1, which are not further discussed here.

As mentioned above, according to the packaging substrate structure having an semiconductor chip embedded therein and the method for manufacturing the same of the present invention, the number of layers of the built-up structure disposed in the upper position of the semiconductor chip of the packaging substrate structure is fewer than those of the conventional packaging substrate structure. As a result, the stress imposed on the surface of the semiconductor chip can be reduced and the reliability of the whole package structure can be increased. Besides, the problem of the low yield of the packaging substrate due to the increasing number of layers, that further causes scrapping of the good chips embedded in the substrate, can be avoided. Also, the transmiting efficiency is enhanced because of the shortening of the transmiting path, and noise interference is diminished so as to enhance electrical quality.

Although the present invention has been explained in relation to its preferred embodiment, it is to be understood that many other possible modifications and variations can be made without departing from the scope of the invention as hereinafter claimed.

What is claimed is:

1. A packaging substrate structure having an semiconductor chip embedded therein, which comprises:
a substrate body having a through cavity, wherein the substrate body is a multilayer board which comprises a core board and a first built-up structure disposed on each of the opposite surfaces of the core board, and the first built-up structure has at least one first dielectric layer, at least one first wiring layer disposed on the first dielectric layer, and a plurality of first conductive vias electrically connecting to the first wiring layer;
an semiconductor chip disposed and fixed in the cavity, wherein the semiconductor chip has an active surface and an opposite inactive surface, the active surface of the semiconductor chip has a plurality of electrode pads thereon; and
a second built-up structure disposed on at least one surface of the substrate body as well as one surface of the semiconductor chip, wherein the second built-up structure has at least one second dielectric layer, at least one second wiring layer disposed on the second dielectric layer, and a plurality of second conductive vias, in which parts of the second conductive vias electrically connect to the first built-up structure, and the outermost second wiring layer has a plurality of conductive pads.

2. The packaging substrate structure as claimed in claim 1, wherein another parts of the second conductive vias of the second built-up structure disposed on the active surface of the semiconductor chip as well as the surface of the substrate body electrically connect to the electrode pads of the semiconductor chip.

3. The packaging substrate structure as claimed in claim 1, further comprising a solder mask covering one surface of the second built-up structure, wherein the solder mask has a plurality of openings to expose the conductive pads.

4. The packaging substrate structure as claimed in claim 1, further comprising a solder mask covering one surface having no second built-up structure thereon of the substrate body and covering one surface of the semiconductor chip.

5. The packaging substrate structure as claimed in claim 4, when the surface of the semiconductor chip is an active surface, the solder mask has a plurality of openings to expose the electrode pads on the active surface of the semiconductor chip.

6. The packaging substrate structure as claimed in claim 1, wherein the gap between the semiconductor chip and the cavity is filled with an adhesive material or part of the material of the second dielectric layer to thereby fix the semiconductor chip in the cavity.

7. A method for fabricating a packaging substrate structure having an semiconductor chip embedded therein, comprising:
providing a substrate body having a through cavity, wherein the substrate body is a multilayer board which comprises a core board and a first built-up structure disposed on each of the opposite surfaces of the core board, the first built-up structure having at least one first dielectric layer, at least one first wiring layer disposed on the first dielectric layer, and a plurality of first conductive vias electrically connecting to the first wiring layer;
placing and fixing an semiconductor chip in the cavity, wherein the semiconductor chip has an active surface and an opposite inactive surface, the active surface has a plurality of electrode pads thereon; and
forming a second built-up structure on at least one surface of the substrate body as well as one surface of the semiconductor chip, wherein the second built-up structure has at least one second dielectric layer, at least one second wiring layer disposed on the second dielectric layer, and a plurality of second conductive vias, in which parts of the second conductive vias electrically connect to the first built-up structure, and the outermost second wiring layer has a plurality of conductive pads.

8. The method as claimed in claim 7, wherein another parts of the second conductive vias of the second built-up structure formed on the active surface of the semiconductor chip as well as the surface of the substrate body electrically connect to the electrode pads of the semiconductor chip.

9. The method as claimed in claim 7, further comprising forming a solder mask covering one surface of the second built-up structure, and forming a plurality of openings in the solder mask to expose the conductive pads.

10. The method as claimed in claim 7, further comprising forming a solder mask covering one surface having no second built-up structure thereon of the substrate body and covering one surface of the semiconductor chip.

11. The method as claimed in claim 10, when the surface of the semiconductor chip is an active surface, further comprising forming a plurality of openings to expose the electrode pads on the active surface of the semiconductor chip.

12. The method as claimed in claim 7, wherein the fixing of the semiconductor chip in the cavity is performed by filling the gap between the semiconductor chip and the cavity with an adhesive material, or with part of the material of the second dielectric layer.
